(19) United States
(12) Patent Application Publication
(10) Pub. No.: US 2015/0162727 A1
(43) Pub. Date: Jun. 11, 2015

(54) WITHDRAWABLE CONTROL COMPARTMENT FOR SWITCHGEAR

(71) Applicant: ABB Technology AG, Zurich (CH)

(72) Inventors: Luis Gerardo Macias, San Luis Potosi (MX); Erika Flores, San Luis Potosi (MX); Erick Martinez-Cruz, San Luis Potosi (MX)

(73) Assignee: ABB Technology AG, Zurich (CH)

(21) Appl. No.: 14/623,762

(22) Filed: Feb. 17, 2015

Related U.S. Application Data
(63) Continuation of application No. PCT/EP2013/067575, filed on Aug. 23, 2013.
(60) Provisional application No. 61/696,130, filed on Aug. 31, 2012.

(51) Int. Cl. H02B 13/02; H05K 5/02; H02B 1/04

(52) U.S. Cl. CPC H02B 13/02; H02B 1/04; H05K 5/0247; H05K 5/0217

(57) ABSTRACT

A withdrawable control compartment for mounting breaker control and measurement devices therein is provided. The compartment is withdrawable upon rollers and allows for quick disconnection of the devices from the energized parts of the switchgear. The compartment is secured in a cell of a switchgear enclosure using flanges in removeable engagement with brackets. The flanges are attached to the compartment and the brackets are attached to opposing sides of the frame of the switchgear enclosure.

### FIELD OF INVENTION

The present application is directed to a control compartment for electrical switchgear.

### BACKGROUND

Electrical switchgear installations, particularly for low voltage applications, often have breaker control and measurement devices mounted in a dedicated control compartment. In order to perform maintenance or replace the devices installed in the dedicated control compartment, the devices must be disconnected or otherwise segregated from the electrical power source. Known compartments for housing breaker control and measurement devices must be completely disassembled in order to disconnect the compartments from the power source and commence maintenance on the devices. Thus, there is a need for improvement in control compartment design of electrical switchgear.

### SUMMARY

An object of the present invention is to provide electrical switchgear having at least one withdrawable compartment that is removeable from the switchgear cell in which the at least one withdrawable compartment is housed. The at least one withdrawable compartment is removeable from the cell on rollers that are mounted in and protrude from a base of the cell. The rollers contact a bottom surface of the withdrawable compartment when the withdrawable compartment is removed from or inserted into the cell.

A withdrawable compartment for mounting electrical devices therein, has a top wall, bottom wall, side walls, and a rear wall. The withdrawable compartment is adapted for removeably mounting in a cell of an electrical switchgear unit and is removeable on rollers protruding from a surface of the bottom wall. The rollers contact a bottom surface of the withdrawable compartment when the withdrawable compartment is removed from or inserted into the corresponding cell of the switchgear unit.

### BRIEF DESCRIPTION OF THE DRAWINGS

In the accompanying drawings, structural embodiments are illustrated that, together with the detailed description provided below, describe exemplary embodiments of a withdrawable control compartment for switchgear. One of ordinary skill in the art will appreciate that a component may be designed as multiple components or that multiple components may be designed as a single component.

Further, in the accompanying drawings and description that follow, like parts are indicated throughout the drawings and written description with the same reference numerals, respectively. The figures are not drawn to scale and the proportions of certain parts have been exaggerated for convenience of illustration.

FIG. 1 is a perspective view of a switchgear enclosure having at least one withdrawable compartment and a front door removed from the least one withdrawable compartment;

FIG. 2a shows the at least one withdrawable compartment having the front door and a handle mounted thereon;

FIG. 2b shows the at least one withdrawable compartment having the front door and a latch mounted therein;

FIG. 3 shows the at least one withdrawable compartment having the front door removed;

FIG. 4 is a side view of the at least one withdrawable compartment showing an inset of a knock-out panel;

FIG. 5 is perspective view of a cell of the switchgear enclosure, further depicting rollers in an inset; and

FIG. 6 is a side view of the at least one withdrawable compartment secured in a cell of the switchgear enclosure.

### DETAILED DESCRIPTION

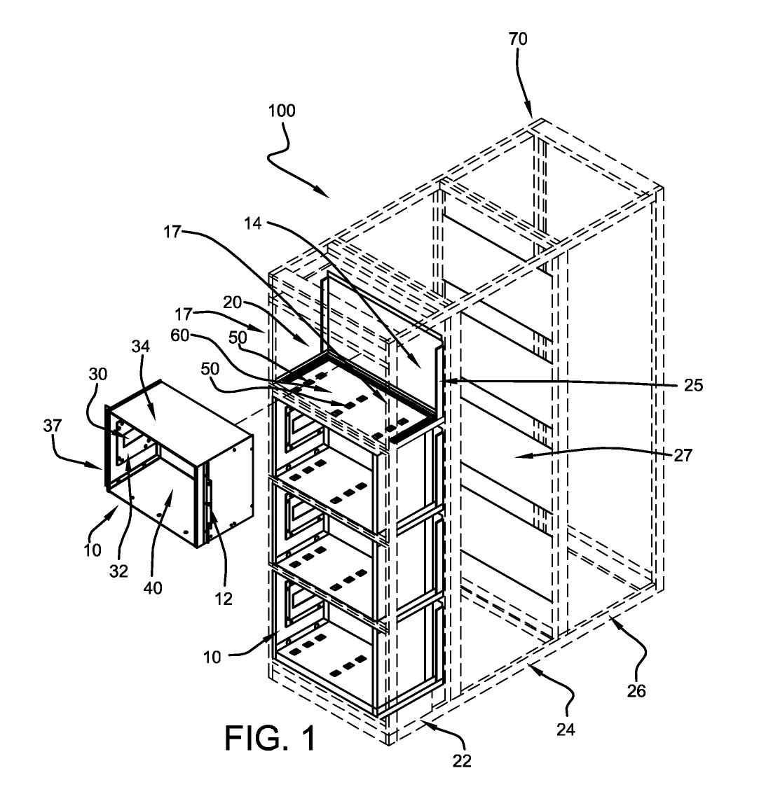

With reference to FIG. 1, a low-voltage electrical switchgear 100 is depicted. The switchgear 100 is housed by an enclosure 70 having at least one withdrawable compartment 10, a device section 22, a bus bar section 24, and a cable section 26. The enclosure 70 is formed from reinforced sheet metal. The device, bus bar, and cable sections 22, 24, 26 are separated by walls 27 that are formed of connected panels of sheet metal.

Low voltage, as used herein, generally refers to voltages that do not exceed 600 volts. Although the low voltage electrical switchgear (hereinafter “switchgear”) is depicted, it should be understood that the enclosure 70 and the at least one withdrawable compartment 10 may be adapted for use in medium voltage switchgear applications that range from about 600 volts to about 38 kV.

With continued reference to FIG. 1, the enclosure 70 has cells 14 for housing withdrawable devices such as circuit breakers, instruments, meters, and control devices. The enclosure 70 depicted has four cells 14 vertically arranged, three of which have the at least one withdrawable compartment 10 mounted therein and the uppermost cell has the withdrawable compartment 10 removed. It should be understood that the switchgear configuration, including the number of cells 14, may differ depending on the application.

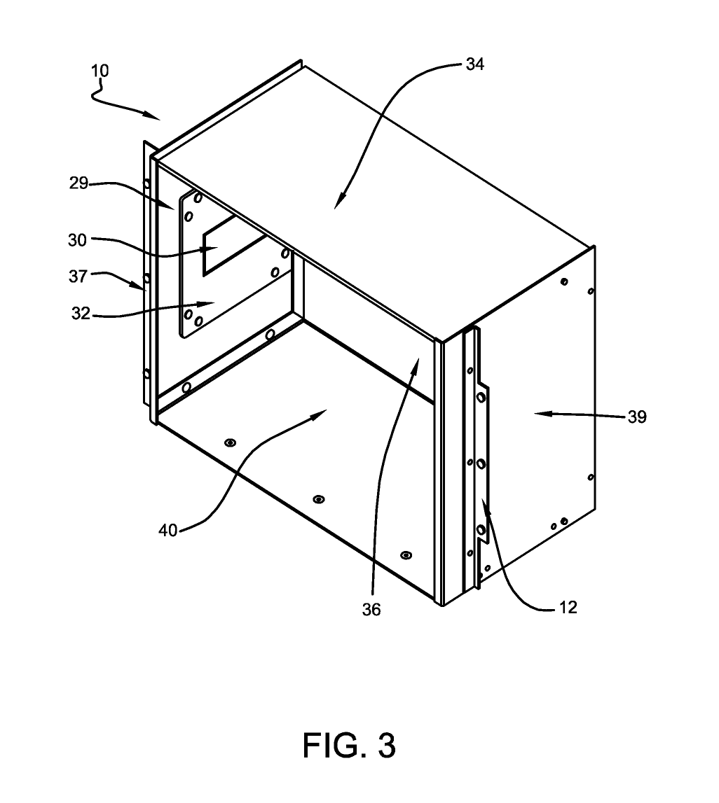

Referring now to FIG. 3, the at least one withdrawable compartment 10 has top, side, rear and bottom walls 34, 29, 39, 36, 40. The at least one withdrawable compartment 10 is removeable from the enclosure 70 to provide quick disconnection and isolation from electrical power to the devices mounted inside the at least one withdrawable compartment 10.

The devices are typically mounted to the rear and bottom walls 36, 40 of the at least one withdrawable compartment 10. The at least one withdrawable compartment 10 houses devices such as the following: meters, terminal blocks, relays, breaker control switches, push buttons, pilot lights, mini-breakers, fuses and other instrumentation used in breaker control.

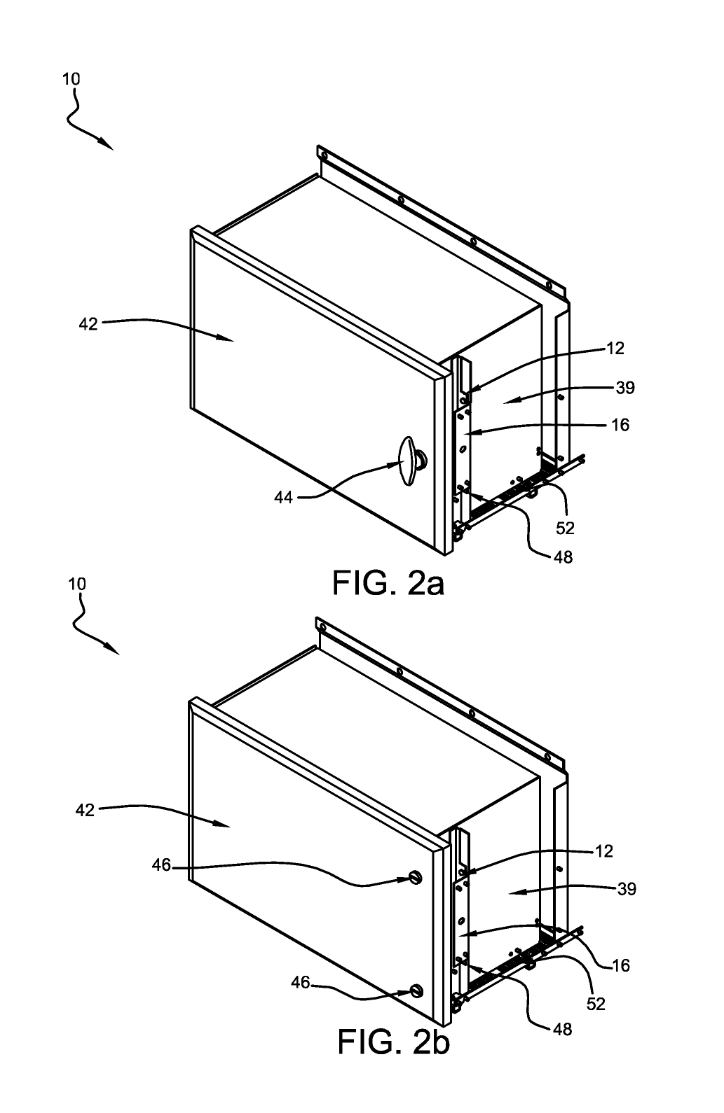

Referring now to FIGS. 2a and 2b, a front door 42 is provided to secure the devices in the at least one withdrawable compartment 10 and further secure the at least one withdrawable compartment 10 in the corresponding cell 14. The front door 42 is secured by a handle 44 or a latch 46, such as a quarter-turn latch. In one embodiment, the handle 44 is a t-handle and the rotation of the handle 44 causes attached rods to engage with or release from a recess in a wall of the corresponding cell 14. The embodiment having the exemplary t-handle and attached rods renders the at least one withdrawable compartment 10 resistant to arc flashes.

The at least one withdrawable compartment 10 has flanges 12, 37 mounted proximate to a front edge 48 of each of the side walls 29, 39. The flanges 12, 37 extend outward from the side walls 29, 39, respectively. The flanges 12, 37 are removeably secured to brackets 16, 19, further securing the compartment 10 in place in the corresponding cell 14. One of the flanges 37 is a flat metal bar having a uniform edge and the other flange 12 has an extension piece extending from the center of a flat metal bar.

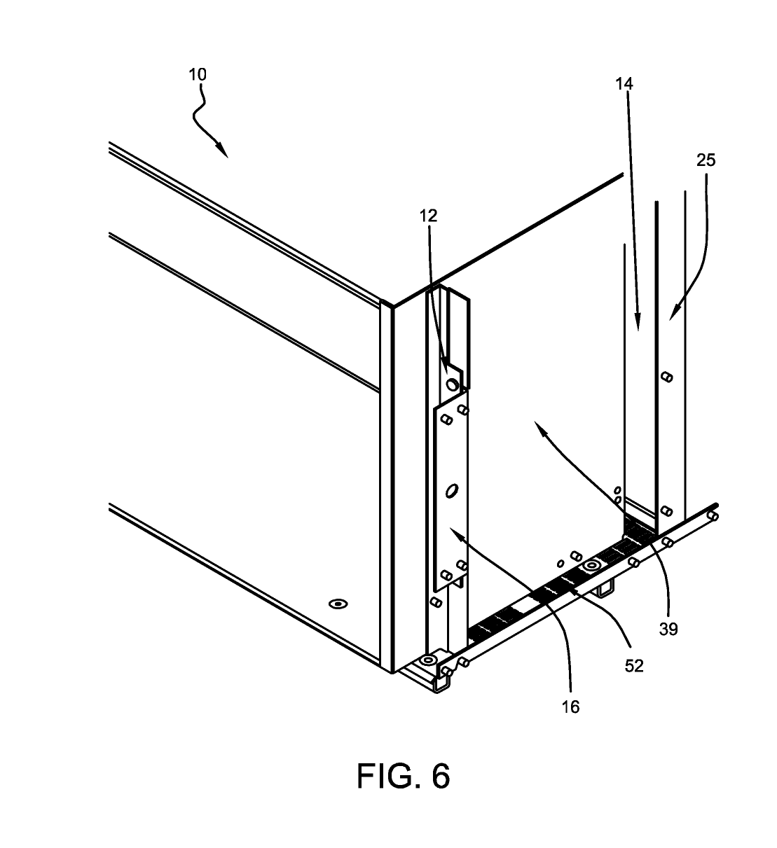

Each of the brackets 16, 19 are attached to the periphery of the frame 70 of the switchgear 100 and extend between a top and bottom surface of the corresponding cell 14. The brackets 16, 19 releasably engage with the flanges 12, 37. The brackets 16, 19 are releasably engaged to the flanges 12, 37 by bolting the brackets 16, 19 to the corresponding one of the flanges 12, 37 as shown in FIG. 6 or disengaged by removing the bolt that secures the bracket 16, 19 to the corresponding flange 12, 37.

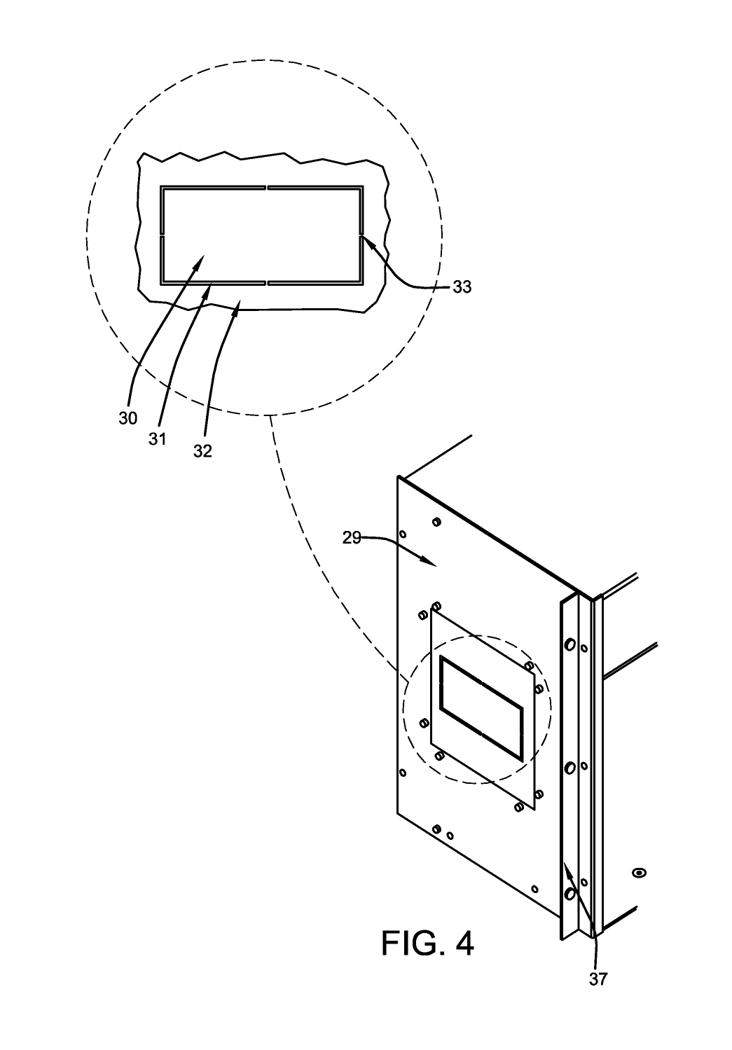

Referring now to FIG. 4, the withdrawable compartment 10 has a knock-out panel 30 formed in a side wall 29, 39. The knock-out panel 30 is die-cut to form perforations 31 in the sheet metal that hold each of the sides of the knock-out panel 30 in place along the side wall 29, 39. Although the knock-out panel 30 is depicted as rectangular in FIG. 4, it should be understood that any shape suitable for the application may be used.

The knock-out panel 30, when removed by severing the attached edges of the perforations 31, allows cables and other connections made between the control compartment devices and power supply to be fed through the resulting generally rectangular opening 33.

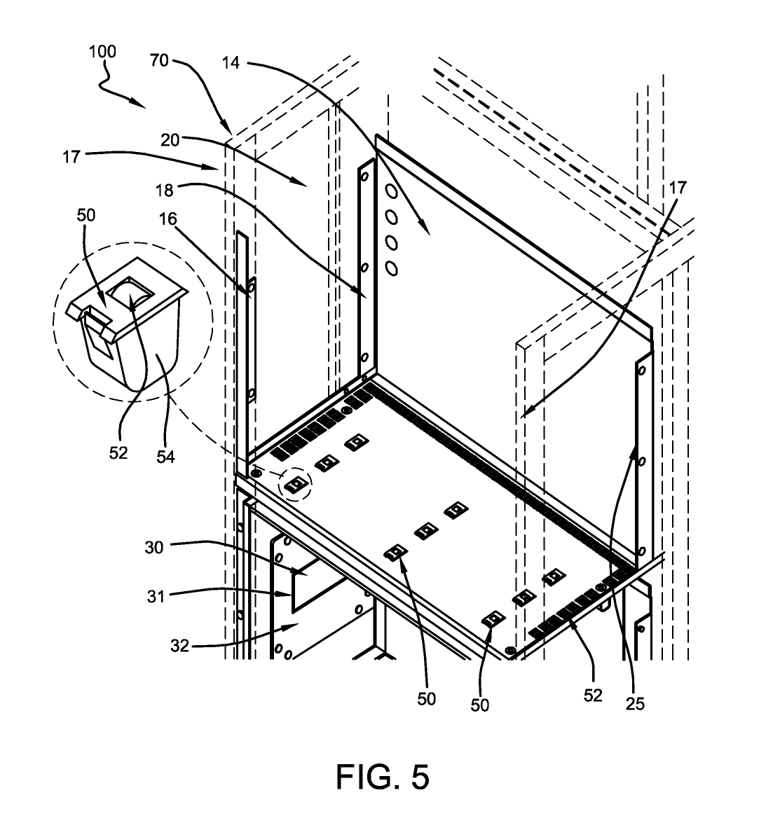

Referring now to FIG. 5, the withdrawable compartment 10 is removeable from or insertable into the corresponding cell 14 of the enclosure 70 along rollers 50 that are mounted in a base of the cell 14. The rollers 50 contact the bottom surface of the compartment, to translate rotational movement of the rollers 50 to linear movement of the compartment 10 along the base 60 of the corresponding cell 14, so that the compartment 10 can be removed from the corresponding cell 14. The wheels of the rollers 50 do not engage with a track, but rather move along the contact surface, the bottom wall 40, of the at least one withdrawable compartment 10 as the at least one withdrawable compartment 10 is being withdrawn from the cell 14.

The rollers 50 have a housing 54 inside which are mounted wheels 52 upon an axle (not shown). The wheels 52 extend slightly above a top surface of the housing 54. There is about 2.5 mm of clearance between the bottom wall 40 of the compartment 10 and the base 60 of the corresponding cell 14. Although nine rollers 50 are depicted in the base 60 of the exemplary cell 14 shown in FIG. 5, it should be understood that any number of rollers 50 suitable for the application may be utilized.

The rollers 50 work in concert with the knock-out panel 30 to facilitate quick electrical disconnection, such as between the control compartment devices and power supply, through the removed knock-out panel 30 and the removal of the compartment 10 from the corresponding cell 14 along the rollers 50.

Grates 52 are disposed proximate to the edges of the bottom surface of the compartment 10. When the compartment 10 is secured in the cell 14 as depicted in FIG. 6, the grates 52 surrounding the compartment 10 are unobstructed. The grates 52 provide ventilation to devices mounted in the device section 22.

While the present application illustrates various embodiments, and while these embodiments have been described in some detail, it is not the intention of the applicant to restrict or in any way limit the scope of the appended claims to such detail. Additional advantages and modifications will readily appear to those skilled in the art. Therefore, the invention, in its broader aspects, is not limited to the specific details, the representative embodiments, and illustrative examples shown and described. Accordingly, departures may be made from such details without departing from the spirit or scope of the applicant's general inventive concept.

What is claimed is:

1. An electrical switchgear comprising:
at least one withdrawable compartment removable from a corresponding cell in a switchgear enclosure, said at least one withdrawable compartment removable upon rollers, said rollers protruding above a top surface of a roller housing mounted in a bottom wall of said corresponding cell, said rollers contacting a bottom wall of said at least one withdrawable compartment when said at least one withdrawable compartment is withdrawn from or enters said corresponding cell.

2. The electrical switchgear of claim 1 wherein said at least one withdrawable compartment is removeably secured inside said cell by a bracket attached to a frame of said switchgear, said bracket extending between top and bottom walls of said cell, said bracket releasably engaging with a flange extending from a side wall of said at least one withdrawable compartment.

3. The electrical switchgear of claim 1 wherein a knock-out panel is formed in a side wall of said at least one compartment.

4. The electrical switchgear of claim 3 wherein when said knock-out panel is removed from said at least one withdrawable compartment, electrical devices mounted inside said corresponding cell can be disconnected from a power source, and said at least one withdrawable compartment can be removed from said corresponding cell of said electrical switchgear.

5. A withdrawable compartment for mounting electrical devices therein, comprising:
a top wall, bottom wall, side walls, and a rear wall, said withdrawable compartment adapted for removeably mounting in a cell of an electrical switchgear, said withdrawable compartment removeable on rollers protruding from a surface of said bottom wall, said rollers contacting a bottom surface of said withdrawable compartment when said withdrawable compartment is removed from or inserted into said cell.

6. The withdrawable compartment of claim 5 wherein when a knock-out panel is removed from said withdrawable compartment side wall, disconnection of said electrical devices mounted inside said withdrawable compartment from a power source is facilitated, and said at least one withdrawable compartment can be removed from said corresponding cell of said electrical switchgear.
